(19) United States
(12) Patent Application Publication
(10) Pub. No.: US 2003/0146864 A1
(43) Pub. Date: Aug. 7, 2003

(54) Electrical signal collector for living body

(75) Inventor: Dan Oun Fang, City of Industry, CA (US)

Correspondence Address: BACON & THOMAS, PLLC, 625 SLATERS LANE, FOURTH FLOOR, ALEXANDRIA, VA, 22314

(73) Assignee: Clover Hi-Tech Corporation, Taipei (TW)

(21) Appl. No.: 10/330,073

(22) Filed: Dec. 30, 2002

(30) Foreign Application Priority Data
Feb. 4, 2002 (TW) 91201246

(51) Int. Cl. H03M 1/00

(52) U.S. Cl. 341/141

(57) ABSTRACT

The apparatus of the present invention comprises: at least one sensor, a bus line, a signal processing unit, a multiplexer, an A/D converter, a serial port interface, an optical fiber and a battery power source. The sensor is attached to the living body for sensing signals. The bus line is connected to the sensor for receiving the sensed signals. The signal processing unit has multiple signal processing circuits for generating multiple analog signals in response to the sensed signals. The multiplexer is connected to the signal processing unit for selecting one of the analog signals. The A/D converter converts the selected analog signal into a serial digital signal. The serial port interface adjusts the serial digital signal with standard serial port level. The optical fiber converter converts the adjusted digital signal into an optical signal. The battery power source provides the required power for the apparatus.

### BACKGROUND OF THE INVENTION

1. Field of the Invention

The present invention generally relates to an electrical signal collector for living body. More particularly, the present invention relates to an electrical signal collector for living body without suffering through current surge.

2. Description of the Related Art

The living body, such as a human being, an animal or the like, transmits a great deal of bio-signals by means of tiny currents. In other words, any variation taken place in the currents and the corresponding voltages can be utilized to recognize changes in the physiologies and pathology of the living body. Conventionally, the measurement of the bio-signals relies upon the delicate electronic device to analyze the currents within the living body. However, current surge may occur sometimes while the conventional electronic device is powered unstably. If occurring during the period of measurement, the current surge may affect the physiologies of the measured living body, or, even worse, cause damage thereto. Thus, there is a need for an apparatus for processing the bio-signals gathered from the living body without suffering through the current surge.

### SUMMARY OF THE INVENTION

It is therefore an object of the present invention to provide an electrical signal collector for living body without suffering through any current surge during measurement. The electrical signal collector for living body of the present invention makes use of an optical fiber to block current from the living body so as to recognize the psychologies thereof safely.

For the foregoing object, the present invention provides an electrical signal collector for living body. The electrical signal collector for living body of the present invention comprises: at least one sensor, a bus line, a signal processing unit, a multiplexer, an A/D converter, a serial port interface, an optical fiber and a battery power source. The sensor is attached to the living body for sensing the signals. The bus line is connected to the sensor for receiving the sensed signals; a signal processing unit having a plurality of signal processing circuits for generating a plurality of analog signals in response to the sensed signals. The multiplexer is connected to the signal processing unit for selecting one of the plurality of the analog signals. The A/D converter is employed for converting the selected analog signal into a serial digital signal. The serial port interface is used for adjusting the serial digital signal with standard serial port level. The optical fiber converter is utilized for converting the adjusted digital signal into an optical signal. The battery power source provides the required power for the apparatus.

### BRIEF DESCRIPTION OF DRAWINGS

The following detailed description, given by way of examples and not intended to limit the invention to the embodiments described herein, will best be understood in conjunction with the accompanying drawings, in which:

FIG. 1 schematically depicts the block diagram of the electrical signal collector for living body in accordance with one preferred embodiment of the present invention;

FIG. 2 depicts the schematic diagram for processing the bio-signals gathered from a living body in accordance with the one preferred embodiment of the present invention; and

FIG. 3 schematically depicts the block diagram of the bio-signal processing unit of FIG. 1.

### DETAILED DESCRIPTION OF THE INVENTION

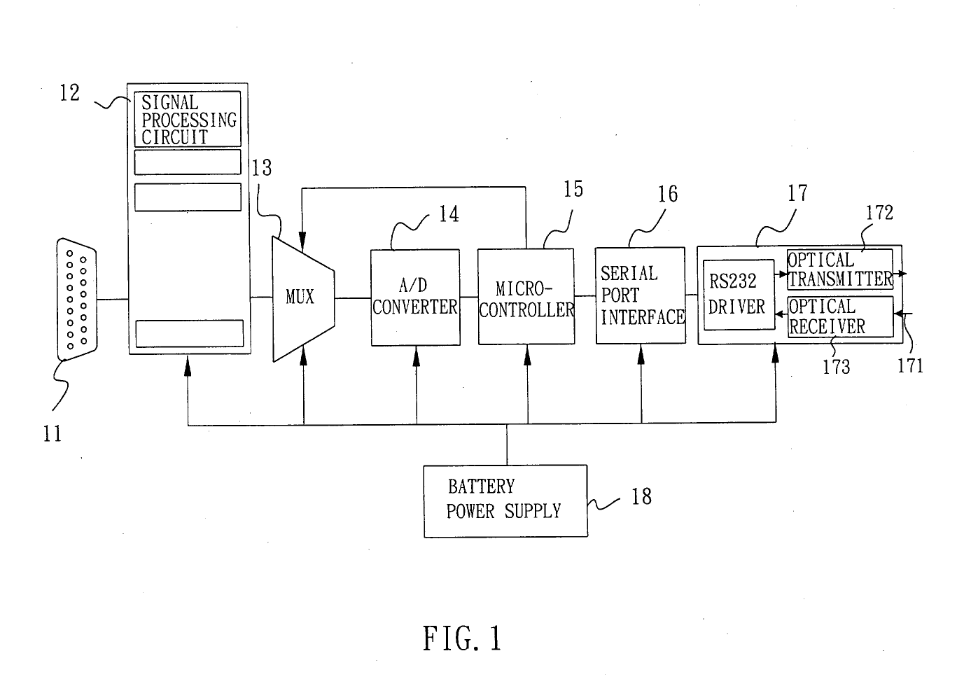

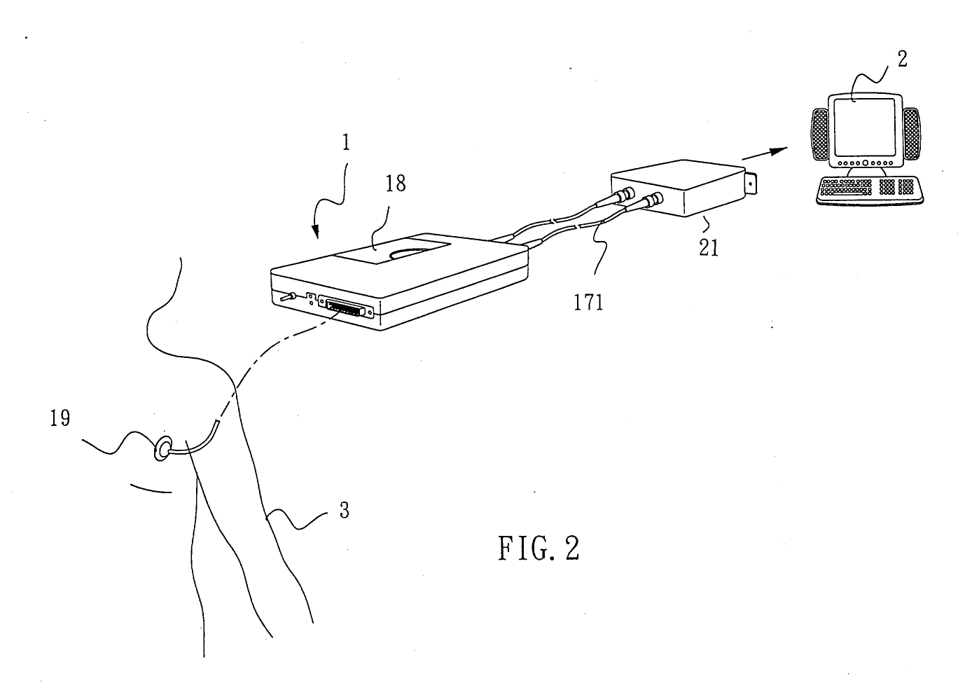

Referring to FIGS. 1 and 2, FIG. 1 schematically depicts the block diagram of the circuit in accordance with one preferred embodiment of the present invention, and FIG. 2 depicts the schematic diagram for processing the bio-signals gathered from a living body 3 in accordance with the one preferred embodiment of the present invention. In FIG. 2, a device 1 for processing bio-signals of the living body is provided with a sensor 19 having one end attached to the living body 3, such as a human being as an example. The sensor 19 has another end connected to a bus line 11, which has several signal lines, for example, 5˜12 signal lines and one ground line.

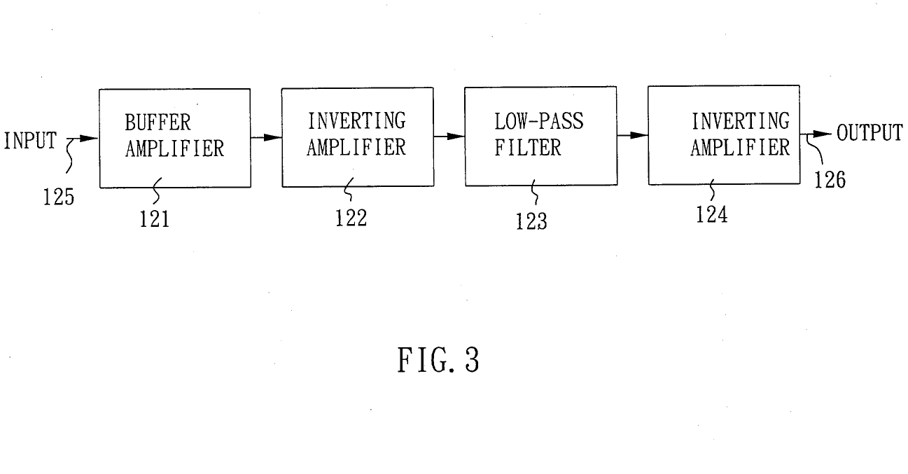

Referring to FIG. 1, the bio-signals within the living body 3 are measured by the sensor 19 and transmitted through the bus line 11 to a bio-signal processing unit 12. The bio-signal processing unit 12 is provided with several signal processing circuits for processing the signals transmitted through the signal lines of the bus line 11. As shown in FIG. 3, the block diagram of each signal processing circuit of the bio-signal processing unit 12 in accordance with the present invention is depicted schematically. In the drawing, the signal processing circuit comprises: a buffer amplifier 121, a first inverting amplifier 122, a low-pass filter 123, a second inverting amplifier 124, which are connected in series, for electrically processing an input signal received from an input terminal 125 in form of four stages. In consideration of impedance, the input signal should be buffered and amplified by the buffer amplifier 121. Then, the signal is amplified by the inverting amplifier 122 with an amplification factor of about 15˜30 in the second stage. The amplified signal is passed through the low-pass filter 123 to take high-frequency noise away in the third stage. The filtered signal is further amplified by the inverting amplifier 124 with an amplification factor of about 10˜20 in the fourth stage. The further-amplified signal thereafter generated from an output terminal 126 is an analog output signal.

Referring to FIG. 1, the bio-signals processed by means of bio-signal processing unit 12 are thereafter provided to a N-to-1 multiplexer 13 for selecting one of the processed bio-signals. Under the control of a micro-controller 15, the multiplexer 13 selects one of the processed bio-signals to an analog-to-digital (A/D) converter 14 for converting the selected analog signal into the associated digital signal. The digital signal is therefore serially stored into the micro-controller 15, which contains firmware to control the operation of the whole processing apparatus, including the control of timing, the channel selection of the multiplexer 13, the converting sequence of the A/D converter 14, digital data access, the control of serial port, the display of panel LEDs, and so on.

Next, the serial signal stored in the micro-controller 15 is adjusted from TTL level (0-5V) into standard serial port level, such as RS-232 level (−12˜+12V) by a serial port interface 16. The adjusted signal is thereafter converted into an optical signal by an optical converter 17. The optical converter 17 comprises a driver 174, an optical transmitter 172 and an optical receiver 173. The driver 174 is employed for adjusting the driving level of the electrical signal with the RS-232 level so that the optical transmitter 172 can convert the signal from electrical form into optical form. In a word, the adjusted signal is modulated to the optical signal to be transmitted through an optical fiber 171 to an photoelectric converter 21 for being coupled to the input terminal of a computer 2 (as shown in FIG. 2) by means of, for example, a laser diode or a light-emitting diode (LED), wherein the photoelectric converter 21 converts optical signals to electrical signal or vice versa. Conversely, the optical receiver 173 is utilized to convert the signal from optical form to electrical form. In other words, the optical signal transmitted through the optical fiber 171 is received and amplified by, for example, a photo diode to be thereafter processed in electrical form. Accordingly, optoelectronic conversion can block any electrical signal of the computer 2 from the living body 3 so as to avoid possible EMI through the optical fiber 171. The photoelectric converter 21 is powered by the computer 2. Moreover, the processing apparatus 1 is connected to other electronic devices, for example, the computer 2, a printer, a monitor, and so on, via the optical fiber 171 only, but no other conductive line provided therebetween, so that insulative effects of about 10 KV high can be sustained, accordingly. In addition, the processing apparatus 1 according to the present invention is powered by the battery power supply 18 of, for example, four AA batteries (zinc-carbide, alkaline, Ni—Cd, or Ni—H batteries, and each is provided with 1.2˜1.5V), which are unlikely to generate any electric shock doing harm to the measured living body 3. Besides, the device 1 and the photoelectric converter 21 can be packaged together in a box, for example a plastic box, for being conveniently carried and operated.

Referring to FIG. 2, the sensor 19 of the preferred embodiment in accordance with the present invention is attached to the living body 3, the signals of which are transmitted to the electrical signal collector 1 through the sensor 19. The electrical signals gathered by the electrical signal collector 1 are converted into the optical signal to be transmitted through the optical fiber 171 to the computer 2 so that the electrical signal collector 1 can be insulated from other electronic device (the computer 2, the printer, the monitor, and so on,) by about 10 KV sustainability. In addition, the electrical signal collector 1 is powered by four 1.5V DC power sources 18 such that no abrupt current surge does harm to the living body 3 when the bio-signals within the living body 3 being measured.

By taking an electrocardiogram sensor as an example, the micro-controller 15 of the foregoing electrical signal collector 1 gathers the required electrocardiogram data from a human being at a sample rate of about 300 samples per second. Each data are composed of nine channel-voltages, each of which is digitalized by the A/D converter 14 in the resolution of 12 bits. Thus, the micro-controller 15 encrypts the data at a rate of about 30 Kbits (300*9*12) per second, which are transmitted through the serial port interface 16 and the optical converter 17 to the computer 2. The computer 2 has software to decrypt the received data into nine channel-voltages of 12-bit resolution for further processing by means of analysis software.

Therefore, the electrical signal collector for living body of the present invention makes use of the optical fiber to block itself from other electronic devices so that no current surge occurs to do harm to the living body when the bio-signals of the living body is to be measured.

While the invention has been described with reference to various illustrative embodiments, the description is not intended to be construed in a limiting sense. Various modifications of the illustrative embodiments, as well as other embodiments of the invention, will be apparent to those persons skilled in the art upon reference to this description. It is therefore contemplated that the appended claims will cover any such modifications or embodiments as may fall within the scope of the invention defined by the following claims and their equivalents.

What is claimed is:

1. An electrical signal collector for living body, comprising:
at least one sensor attached to the living body for sensing the bio-signals;
a bus line connected to said sensor for receiving said sensed signals;
a signal processing unit having a plurality of signal processing circuits for generating a plurality of analog signals in response to said sensed signals;
a multiplexer connected to said signal processing unit for selecting one of said plurality of said analog signals;
an A/D converter for converting said selected analog signal into a serial digital signal;
a serial port interface for adjusting said serial digital signal with standard serial port level;
an optical fiber converter for converting said adjusted digital signal into an optical signal; and
a battery power source for providing the required power for the apparatus.

2. The electrical signal collector for living body as claimed in claim 1, wherein said signal processing circuits of said signal processing unit comprise a buffer amplifier, one inverting amplifier, a low-pass filter and another inverting amplifier for buffering, first-stage amplifying, filtering and second-stage amplifying said sensed signals, respectively.

3. The electrical signal collector for living body as claimed in claim 2, wherein said one inverting amplifier amplifies said sensed signals with an amplification factor of about 15˜30.

4. The electrical signal collector for living body as claimed in claim 2, wherein said another inverting amplifier amplifies said sensed signals with an amplification factor of about 10˜20.

5. The electrical signal collector for living body as claimed in claim 1, wherein said serial port interface is a RS-232 interface.

6. The electrical signal collector for living body as claimed in claim 1, wherein said power source is a standard battery.

7. The electrical signal collector for living body as claimed in claim 1, wherein said optical fiber converter comprises:
a photo transmitter for modulating and converting said adjusted digital signal into the optical signal to be transmitted to an photoelectric converter through an optical fiber by means of a laser or a light-emitting diode; and
a photo receiver for receiving and amplifying another optical signal transmitted from the photoelectric converter through the optical fiber by a photo diode.
